(19) United States
(12) Patent Application Publication
(10) Pub. No.: US 2026/0267098 A1
(43) Pub. Date: Sep. 10, 2026

(54) OPTICALLY INTERCONNECTED NETWORK INTERFACE CONTROLLER (NIC)

(71) Applicant: Lightmatter, Inc., Mountain View, CA (US)

(72) Inventors: Bradford Turcott, Georgetown, TX (US); Taylor Groves, Poulsbo, WA (US)

(73) Assignee: Lightmatter, Inc., Mountain View, CA (US)

(21) Appl. No.: 19/555,182

(22) Filed: Mar. 3, 2026

Related U.S. Application Data
(60) Provisional application No. 63/766,647, filed on Mar. 4, 2025.

(51) Int. Cl. G02B 6/43; G02B 6/42; H10B 80/00; H10D 80/30

(52) U.S. Cl. CPC G02B 6/43; G02B 6/4206; G02B 6/4246; G02B 6/4278; G02B 6/4295; H10B 80/00; H10D 80/30

(57) ABSTRACT

Described herein are systems that integrate a network interface controller (NIC) with a processing unit through co-packaging to improve bandwidth and latency while reducing power consumption. The NIC may be 3D stacked on top of a photonic interposer. A chip-to-chip interface between the NIC and the processing unit addresses bandwidth bottlenecks and latency associated with conventional PCIe-based approaches. The use of silicon photonics enables optical bandwidth that matches the bandwidth of the chip-to-chip interface while reducing power consumption compared to conventional approaches using active optical cables. The photonic interposer may include SRAM buffers for retransmission operations.

### CROSS-REFERENCE TO RELATED APPLICATIONS

This application claims the benefit under 35 U.S.C. § 119(e) of U.S. Provisional Application Ser. No. 63/766,647, filed on Mar. 4, 2025, under Attorney Docket No. L0858.70121US00 and entitled “3D STACKED ENGINE WITH AN INTEGRATED NETWORK INTERFACE CONTROLLER (NIC),” which is hereby incorporated herein by reference in its entirety.

### BACKGROUND

Modern data centers use thousands of computer processors for high-performance computing (HPC) tasks such as those required in artificial intelligence (AI) and machine learning (ML) applications. To achieve these tasks, the processors (referred to as xPUs, which could be for example central processing units (CPUs), graphics processing units (GPUs), or other application-specific integrated circuits (ASICs)) send data to/from each other and to/from memory devices. Conventional data centers employ external network interface controllers (NICs) connected to xPUs via Peripheral Component Interconnect Express (PCIe). This architecture utilizes active optical cables for inter-rack communication.

### SUMMARY

In some aspects, the techniques described herein relate to a package, including: a photonic integrated circuit (PIC); and an electronic integrated circuit (EIC) mounted on the PIC, the EIC including a network interface controller (NIC).

In some aspects, the techniques described herein relate to a package, wherein the EIC further includes a chip-to-chip interface configured to permit communication between the NIC and a processing unit.

In some aspects, the techniques described herein relate to a package, wherein the chip-to-chip interface is a Universal Chiplet Interconnect Express (UCIe) interface.

In some aspects, the techniques described herein relate to a package, further including a substrate on which the PIC is mounted, the substrate including a silicon bridge coupling the NIC with the processing unit.

In some aspects, the techniques described herein relate to a package, wherein the EIC further includes a plurality of serializer/deserializer (SerDes), each SerDes interfacing with the PIC.

In some aspects, the techniques described herein relate to a package, wherein the PIC further includes a plurality of tiles, each tile including: a transceiver including an optical modulator and a photodetector; and an optical switch configured to selectively couple optical signals between the transceiver and a bus waveguide.

In some aspects, the techniques described herein relate to a package, wherein the plurality of tiles form a programmable optical network having dimensions greater than 24.8 mm by 32 mm.

In some aspects, the techniques described herein relate to a package, wherein the PIC includes a plurality of SRAM buffers configured to store data for retransmission buffering operations.

In some aspects, the techniques described herein relate to a package, wherein the NIC is configured to communicate with the plurality of SRAM buffers to retrieve data for retransmission.

In some aspects, the techniques described herein relate to a package, wherein the SRAM buffers are embedded in the PIC through heterogeneous integration.

In some aspects, the techniques described herein relate to a compute node, including: a substrate; a photonic integrated circuit (PIC) mounted on the substrate; an electronic integrated circuit (EIC) mounted on the PIC, the EIC including a network interface controller (NIC) and a first chip-to-chip interface; and a processing unit mounted on the substrate and including a second chip-to-chip interface in communication with the first chip-to-chip interface through the substrate.

In some aspects, the techniques described herein relate to a compute node, wherein the first and second chip-to-chip interfaces are Universal Chiplet Interconnect Express (UCIe) interfaces.

In some aspects, the techniques described herein relate to a compute node, wherein the substrate includes a silicon bridge coupling the first and second chip-to-chip interfaces together.

In some aspects, the techniques described herein relate to a compute node, further including a high bandwidth memory (HBM) mounted on the substrate and coupled to the processing unit.

In some aspects, the techniques described herein relate to a compute node, wherein the EIC further includes a plurality of serializer/deserializer (SerDes), each SerDes interfacing with the PIC.

In some aspects, the techniques described herein relate to a compute node, wherein the PIC further includes a plurality of tiles, each tile including: a transceiver including an optical modulator and a photodetector; and an optical switch configured to selectively couple optical signals between the transceiver and a bus waveguide.

In some aspects, the techniques described herein relate to a compute node, wherein the plurality of tiles form a programmable optical network having dimensions greater than 24.8 mm by 32 mm.

In some aspects, the techniques described herein relate to a compute node, wherein the PIC includes a plurality of SRAM buffers configured to store data for retransmission buffering operations.

In some aspects, the techniques described herein relate to a compute node, wherein the NIC is configured to communicate with the plurality of SRAM buffers to retrieve data for retransmission.

In some aspects, the techniques described herein relate to a compute node, further including a pluggable optical connector configured to couple optical fibers to the PIC.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1 illustrates a top view of a package with an integrated network interface controller, according to some embodiments.

FIG. 2A illustrates a cross-section view of the package of FIG. 1, according to some embodiments.

FIG. 2B illustrates a detailed view of a photonic integrated circuit and electronic integrated circuit architecture, according to some embodiments.

FIG. 3 illustrates a cross-section of an optical engine co-packaged with a processing unit using an embedded multi-die interconnect bridge, according to some embodiments.

FIG. 4 illustrates a cross-section of an optical engine co-packaged with a processing unit using standard packaging, according to some embodiments.

FIG. 5 illustrates a top view of a compute node including optical engines, processing units and memory, according to some embodiments.

### DETAILED DESCRIPTION

Described herein are optically interconnected network interface controllers (NICs). Aspects of the present disclosure relate to a package including a photonic integrated circuit (PIC) serving as a photonic interposer and an electronic integrated circuit (EIC) including NIC logic. The package may be used as part of an optical engine interconnecting processing units (xPUs) and high bandwidth memory (HBM) with external devices optically. In some embodiments, the optical engine may include a 3D stacked configuration in which the EIC is mounted on the PIC, enabling high-bandwidth, low-latency communication while reducing power consumption compared to conventional approaches.

A network interface controller (NIC), sometimes referred to as a network interface card or network adapter, is a hardware component that connects a computing device to a computer network. In conventional systems, NICs are implemented as external cards that connect to processors via a Peripheral Component Interconnect Express (PCIe) interface, for example. NICs may implement various network protocols and standards, including Ethernet (such as 10 Gigabit Ethernet, 25 Gigabit Ethernet, 40 Gigabit Ethernet, 100 Gigabit Ethernet, 200 Gigabit Ethernet, or 400 Gigabit Ethernet), InfiniBand, and Remote Direct Memory Access (RDMA) protocols such as RDMA over Converged Ethernet (RoCE) and Internet Wide Area RDMA Protocol (iWARP). In data center environments, NICs play a role in enabling communication between servers within a rack (intra-rack communication) and between servers in different racks (inter-rack communication). Conventional data center architectures may utilize active optical cables for inter-rack communication to achieve the bandwidth and reach requirements of modern high-performance computing (HPC) applications.

The inventors have recognized and appreciated that using external NICs connected to xPUs via PCIe has several drawbacks. These drawbacks include bandwidth limitations imposed by the PCIe interface, increased latency due to the communication path between the external NIC and the processor, and significant power consumption associated with driving signals across the PCIe interface. The inventors have further recognized and appreciated that the use of active optical cables in conventional data center architectures also increases cost and power consumption, as active optical cables require electrical-to-optical and optical-to-electrical conversion at each end of the cable. These factors pose challenges in meeting the growing demands of modern machine learning (ML) applications, which may require increased bandwidth and reduced latency while also aiming for lower power consumption and higher compute density. The inventors have further recognized and appreciated that using 2D packaging designs, memory buffers for data retransmission would take up a large portion of the chip area, limiting the available area for other functional components and constraining the overall system architecture.

Recognizing these limitations, the inventors have developed systems and methods that integrate the NIC with the xPU through co-packaging in a solution that improves bandwidth and latency while reducing power consumption. In some embodiments, a NIC may be 3D stacked on top of a PIC. The PCIe bandwidth bottleneck and latency may be addressed in some embodiments by using a chip-to-chip interface (also referred to as die-to-die (D2D) interface) between the NIC and the xPU. In some embodiments, the chip-to-chip interface may be a Universal Chiplet Interconnect Express (UCIe) interface. In other embodiments, the chip-to-chip interface may be a Bunch of Wires (BoW) interface, an Advanced Interface Bus (AIB) interface, a Compute Express Link (CXL) interface, a High Bandwidth Memory (HBM) interface, an Open High Bandwidth Interconnect (OpenHBI) interface, or other suitable die-to-die interface technologies.

In some embodiments, this approach may achieve at least a 10× increase in bandwidth relative to state-of-the-art NICs while simultaneously reducing the latency. Conventional chip-to-chip interfaces are typically limited to interconnection distances of 2.5 cm or less due to power consumption, latency, and bandwidth constraints associated with electrical signaling over longer distances. By enabling these interfaces to operate in the optical domain, these constraints are substantially reduced, allowing for longer interconnection distances and, as a result, more complex computer architectures that would not be feasible with purely electrical interconnects.

The PIC may be implemented using silicon photonics technology. Silicon photonics leverages existing complementary metal-oxide-semiconductor (CMOS) fabrication infrastructure, enabling high-volume manufacturing at reduced cost compared to other photonic platforms. The use of silicon as the primary material allows for integration with standard semiconductor manufacturing processes, providing access to mature fabrication techniques, high yield, and economies of scale. Additionally, silicon photonics enables the integration of optical components with electronic circuits on a common platform, facilitating compact and efficient system designs.

In some embodiments, the PIC includes a programmable optical network that can dynamically place any component of a network in optical communication with any other component of the network. This programmable optical network may include optical switches, waveguides, and other photonic elements that can be configured to establish optical paths between different endpoints. The ability to dynamically reconfigure the optical network enables flexible routing of optical signals, which may be advantageous for adapting to varying traffic patterns, implementing fault tolerance, and optimizing network performance based on application requirements.

In some embodiments, the PIC may be implemented using optical reticle-stitching techniques. Optical reticle-stitching involves combining multiple lithographic exposures to create a photonic circuit that is larger than what can be achieved with a single reticle shot. A single reticle shot is typically limited to an area of approximately 24.8 mm by 32 mm due to the field size constraints of lithographic exposure tools. By optically stitching together multiple reticle shots, the PIC can form optical networks that are significantly larger than this single-shot limitation. In some embodiments, the programmable optical network formed by the plurality of tiles may have dimensions greater than 24.8 mm by 32 mm. For example, the optical network may have a first dimension X that is greater than 24.8 mm and a second dimension of 32 mm, or a first dimension of 24.8 mm and a second dimension Y that is greater than 32 mm, or both a first dimension X greater than 24.8 mm and a second dimension Y greater than 32 mm. The use of reticle-stitching enables the creation of large-scale photonic interposers that can accommodate multiple EICs, xPUs, and other components while maintaining optical connectivity across the entire device.

In some embodiments, the PIC includes SRAM buffers that provide memory storage for data buffering operations. The SRAM buffers may be used by the NIC logic for retransmission buffering, which is a function associated with reliable data transport protocols. When data packets are transmitted over a network, the transmitting device may need to retain copies of the transmitted data until acknowledgment of successful receipt is received from the destination. If acknowledgment is not received within a specified time period, or if a negative acknowledgment is received indicating transmission failure, the NIC logic may retrieve the data from the SRAM buffers and retransmit the packets. Additionally, when data is received, it may be temporarily stored in the SRAM buffers on the NIC before being written to a host's memory. The use of SRAM for these buffering operations provides low-latency access to the buffered data due to the fast and local nature of SRAM, which may be advantageous for maintaining high throughput in network communications. In some embodiments, because there is available area within the PIC layer, the SRAM buffers may be positioned within this layer, which frees up area in the EIC for logic and other functional components.

In some embodiments, the SRAM buffers may be embedded within the PIC itself. For example, the SRAM buffers may be co-integrated with the PIC using mixed silicon photonics and complementary metal-oxide-semiconductor (CMOS) monolithic processes. In other embodiments, the SRAM buffers may be implemented as one or more separate memory dies that are bonded to the PIC. The bonding may be accomplished using various techniques such as hybrid bonding, micro-bump bonding, or other die-to-die attachment methods. By positioning the SRAM buffers within or on the PIC in the 3D stacked configuration, the memory is located in close proximity to the NIC logic, which may reduce the latency associated with accessing the buffered data compared to configurations where the memory is located farther from the NIC logic.

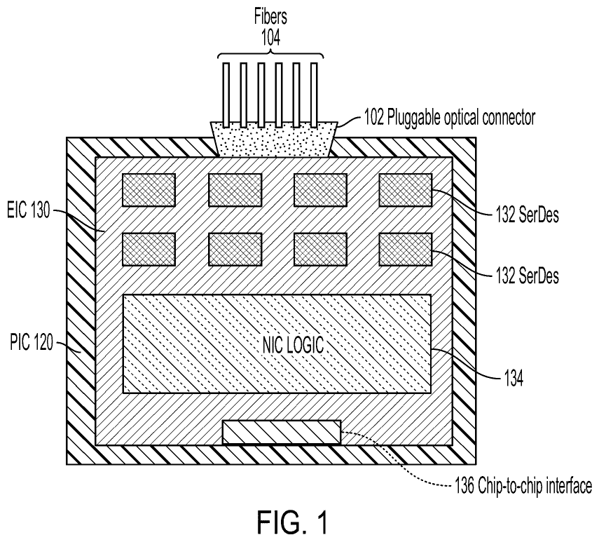

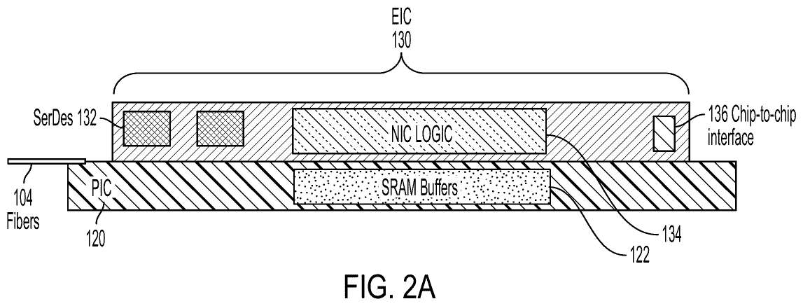

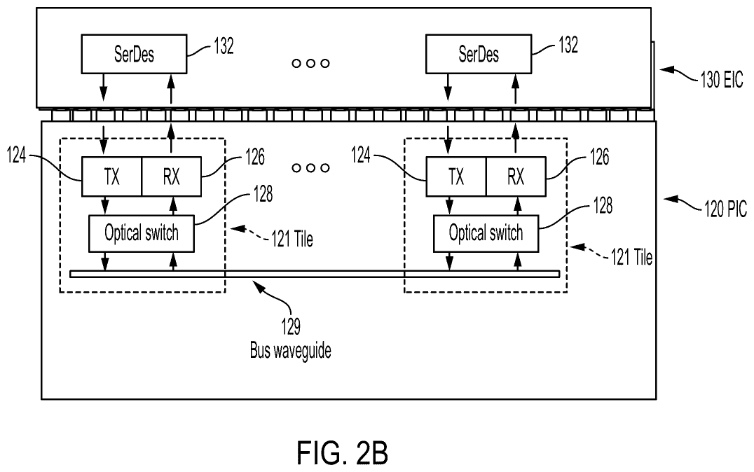

FIG. 1 and FIG. 2A illustrate a top view and a side view of a package with an integrated network interface controller (NIC), according to some embodiments. As shown in FIG. 1, the package includes a photonic integrated circuit (PIC) 120, an electronic integrated circuit (EIC) 130, a pluggable optical connector 102, and fibers 104. The EIC 130 includes a plurality of serializer/deserializer (SerDes) 132, NIC logic 134, and a chip-to-chip interface 136. The EIC 130 is mounted on the PIC 120 in a 3D stacked configuration.

The PIC 120 serves as a photonic interposer in the 3D stacked configuration. In some embodiments, the PIC 120 may be implemented using silicon photonics technology, which leverages complementary metal-oxide-semiconductor (CMOS) fabrication infrastructure. The PIC 120 may include optical waveguides, optical modulators, photodetectors, and other photonic components configured to transmit and receive optical signals (as described in more detail with reference to FIG. 2B). In the 3D stacked configuration, the PIC 120 provides a platform upon which the EIC 130 is mounted, enabling close integration between the electronic and photonic components of the optical engine.

The EIC 130 may be fabricated using CMOS technology and may be bonded to the PIC 120 using hybrid bonding, micro-bump bonding, or other suitable die-to-die attachment methods. In the arrangement of FIG. 1, the entire bottom surface of the EIC 130 is mounted on the PIC 120. However, not all embodiments are limited in this respect. In some embodiments, the bottom surface of the EIC 130 may be in part on the PIC 120 and in part may extend beyond the edge of the PIC 120, resting on an encapsulant. Pillars may place that portion of the EIC 130 in electrical communication with the underlying substrate that supports the PIC 120.

The SerDes 132 may be arranged in an array configuration within the EIC 130, as shown in FIG. 1. The SerDes 132 may be configured to perform serialization of parallel data for transmission and deserialization of serial data upon reception. The SerDes 132 may interface with corresponding optical transmitters and receivers in the PIC 120.

The NIC logic 134 may be co-integrated with the SerDes within the EIC 130, as shown in FIG. 1. By moving the NIC logic from the board (as is the case in conventional systems) to the package (as described herein), copper traces and infrastructure of a discrete NIC mounted on a board can be removed, significantly improving performance. The NIC logic 134 may be configured to implement network protocols, manage packet routing, handle flow control, and perform other network interface functions. In some embodiments, the NIC logic 134 may implement protocols such as Ethernet, InfiniBand, Remote Direct Memory Access (RDMA) protocols, Ultra Ethernet Consortium (UEC) protocols, Ultra Accelerator Link (UAL), or Scalable Unified Ethernet (SUE). In some embodiments, the NIC logic 134 may include application-specific logic to support higher-level machine learning (ML) or high-performance computing (HPC) libraries, such as message passing interfaces and shared memory (SHMEM) operations. The NIC logic 134 communicates with the xPU through the chip-to-chip interface 136, enabling the exchange of data between the processing unit and the network. The NIC logic 134 also interfaces with the SerDes 132 to transmit and receive serialized data, which is then converted to optical signals by the PIC 120 for communication with external devices over the fibers 104. In some embodiments, the NIC logic 134 may communicate with the SRAM buffers 122 in the PIC 120 to store data for retransmission buffering operations. The NIC logic 134 may further interface with remote computing nodes, network switches, storage devices, and other optical engines in a data center environment through the optical network provided by the PIC 120.

The chip-to-chip interface 136 may be located at a peripheral region of the EIC 130, for example. The chip-to-chip interface 136 may be configured to permit high-bandwidth, low-latency communication between the optical engine and external components such as an xPU. In some embodiments, the chip-to-chip interface 136 may implement a UCIe interface. In other embodiments, the chip-to-chip interface 136 may implement a BoW interface, an AIB interface, a CXL interface, an HBM interface, an OpenHBI interface, or other suitable die-to-die interface technologies.

The pluggable optical connector 102 and fibers 104 provide optical connectivity for the optical engine. The pluggable optical connector 102 may be configured to receive the fibers 104 and provide optical coupling between the fibers 104 and the PIC 120. In some embodiments, the pluggable optical connector 102 may enable field-replaceable optical connections, allowing fibers to be connected and disconnected without requiring permanent attachment. The fibers 104 may include single-mode fibers, multi-mode fibers, polarization-maintaining fibers, hollow-core fibers, or a combination thereof, depending on the application requirements. The fibers 104 may carry optical signals for communication with external devices, such as other optical engines, network switches, or remote computing nodes in a data center environment.

FIG. 2B illustrates the functional interconnection between the EIC 130 and the PIC 120, according to some embodiments. As shown in FIG. 2B, the PIC 120 includes a plurality of tiles 121, each tile 121 including a transmitter (TX) 124, a receiver (RX) 126, and an optical switch 128. The tiles 121 are interconnected by a bus waveguide 129. Each SerDes 132 in the EIC 130 interfaces with a corresponding tile 121 in the PIC 120, enabling parallel-to-serial and serial-to-parallel conversion for data transmission and reception.

In some embodiments, the PIC 120 may be a multi-tile PIC fabricated using optical reticle-stitching techniques. Each tile 121 may correspond to a reticle shot. The use of optical reticle-stitching enables the creation of large-scale photonic interposers that can accommodate multiple EICs, xPUs, and other components while maintaining optical connectivity across the entire device.

Each TX 124 may include a modulator driver and an optical modulator (although the modulator driver may be integrated as part of the EIC in some embodiments). The modulator driver may be configured to receive electrical signals from the corresponding SerDes 132 and drive the optical modulator accordingly. The optical modulator may be a microring modulator (MRM), a Mach-Zehnder modulator (MZM), or other types of optical modulators configured to modulate an optical carrier signal based on the electrical input from the modulator driver. In some embodiments, the modulators may implement pulse amplitude modulation 4-level (PAM4) signaling to achieve higher data rates, non-return to zero (NRZ) schemes, or other schemes.

Each RX 126 may include a photodetector and a transimpedance amplifier (TIA) (although the TIA may be integrated as part of the EIC in some embodiments). The photodetector may be configured to convert received optical signals into electrical current. The TIA may be configured to convert the electrical current from the photodetector into a voltage signal suitable for processing by the corresponding SerDes 132 in the EIC 130.

In some embodiments, the PIC 120 may implement a wavelength division multiplexing (WDM) network. In a WDM implementation, each TX 124 may include multiple optical modulators, each configured to modulate a different wavelength channel, and may include (or be connected to) tunable laser sources that can be configured to operate at different wavelengths. The modulated optical signals at different wavelengths may be combined using a wavelength multiplexer for transmission over a common optical path. On the receive side, each RX 126 may include a wavelength demultiplexer configured to separate the received optical signal into its constituent wavelength channels. Each wavelength channel may be directed to a corresponding photodetector, allowing multiple data streams to be received simultaneously over different wavelength channels.

Each transceiver, including a TX 124 and an RX 126, may be connected to a network of bus waveguides 129 through an optical switch 128. The optical switch 128 may be configured to selectively couple optical signals between the transceiver and the bus waveguide 129. In some embodiments, the optical switch 128 may enable any tile 121 to be placed in optical communication with any other tile 121, thereby providing a programmable optical network that can dynamically route optical signals between different endpoints. This programmable optical network may be advantageous for adapting to varying traffic patterns, implementing fault tolerance, and optimizing network performance based on application requirements.

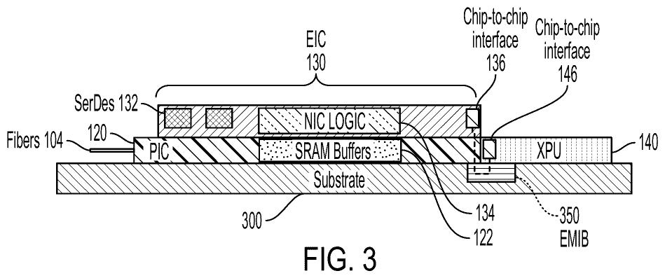

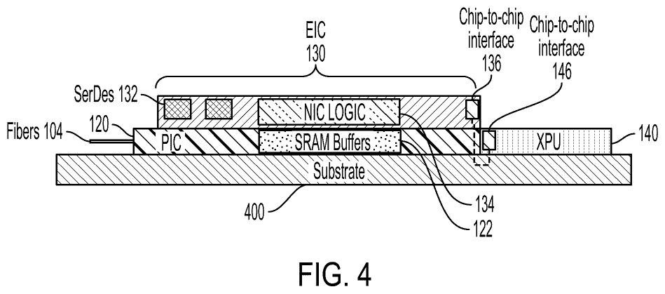

FIG. 3 and FIG. 4 illustrate the package of FIG. 2A as part of an optical engine that further includes a substrate on which the PIC 120 is mounted and an xPU 140, according to some embodiments. The xPU 140 may include various types of processing units, such as a CPU, a GPU, a TPU, an accelerator, an ASIC, an FPGA, or other processing devices configured to perform computational tasks. The xPU 140 communicates with the NIC logic 134 through chip-to-chip interfaces 136 and 146 (which is embedded in xPU 140). In some embodiments, the communication path between the xPU 140 and the NIC logic 134 passes through through silicon vias (TSVs) formed inside the PIC 120.

In the implementation of FIG. 3, an embedded multi-die interconnect bridge (EMIB) 350 is formed as part of substrate 300 and places chip-to-chip interfaces 136 and 146 in communication with each other. It should be noted that the EMIB 350 is one example of a silicon bridge that provides high-density interconnections between the chip-to-chip interface 136 of the EIC 130 and the chip-to-chip interface 146 of the xPU 140. Other examples of silicon bridges that may be used in place of or in addition to the EMIB 350 include Local Silicon Interconnect (LSI), Chip-on-Wafer-on-Substrate (CoWoS) technology (e.g., CoWoS-L or CoWoS-S), interposer-based bridges, and organic interposers with embedded silicon bridges.

In contrast to the implementation shown in FIG. 3, the implementation of FIG. 4 does not include a silicon bridge such as the EMIB 350. Instead, the chip-to-chip interfaces 136 and 146 may communicate via routing within the substrate 400. This approach may provide a lower-cost alternative to silicon bridge-based packaging while still enabling co-packaging of the optical engine with the xPU 140. However, the interconnect density and bandwidth achievable with standard substrate routing may be lower than that achievable with a silicon bridge. The choice between the implementations shown in FIG. 3 and FIG. 4 may depend on the specific bandwidth requirements, cost constraints, and other design considerations of the target application.

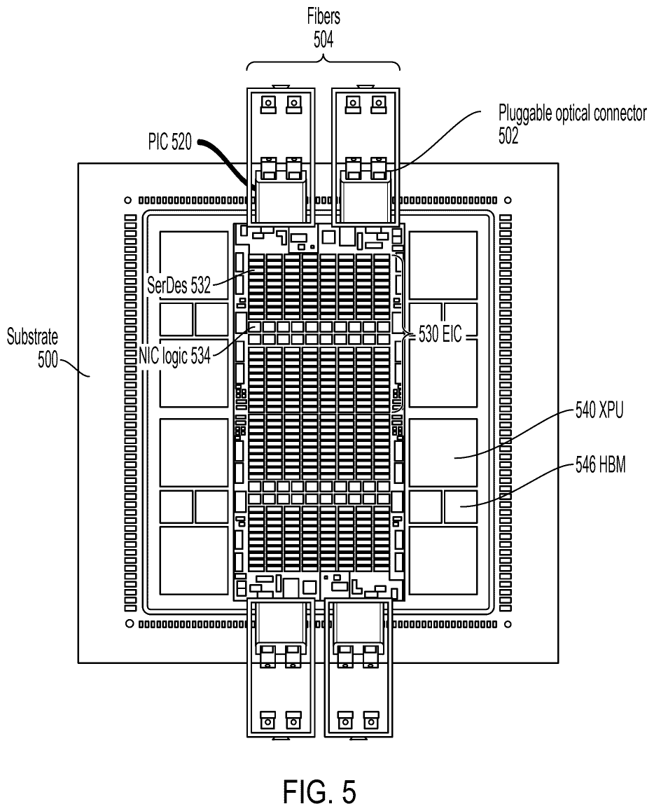

FIG. 5 illustrates a top view of a compute node including optical engines, processing units and memory, according to some embodiments. The configuration shown in FIG. 5 represents an example implementation with multiple xPUs and high bandwidth memory (HBM) stacks co-packaged with the optical engine on a common substrate.

As shown in FIG. 5, the package includes a substrate 500 that serves as the base for mounting the various components. The substrate 500 may be an organic substrate, a silicon substrate, or other suitable packaging substrate configured to provide electrical routing and mechanical support for the mounted components.

The package includes four PICs 520 mounted on the substrate 500. Each PIC 520 may be similar to the PIC 120 described with reference to FIGS. 1-4 and may serve as a photonic interposer for the optical engine. Four pluggable optical connectors 502 are positioned at the top and bottom edges of the substrate 500 and are configured to couple fibers 504 to a respective PIC. The fibers 504 provide optical communication pathways for data transmission to and from external devices such as other optical engines, network switches, or remote computing nodes.

An electronic integrated circuit (EIC) 530 is positioned on top of each PIC 520. The EIC 530 includes SerDes 532 for serialization and deserialization of data signals, as well as NIC logic 534 for network interface control functions. The EIC 530 may be similar to the EIC 130 described with reference to FIGS. 1-4.

The package includes eight xPUs 540 mounted on the substrate 500. In some embodiments, the xPUs 540 may be similar to the xPUs described with reference to FIGS. 3-4. The package further includes eight HBMs 546 stacks that provide high-bandwidth memory access for the xPUs 540. The HBM 546 stacks may be positioned on multiple sides of the xPU 540 to maximize memory bandwidth and minimize latency for memory access operations.

The configuration shown in FIG. 5 demonstrates how the 3D optical engine with integrated NIC may be co-packaged with multiple processing units and memory in a unified package architecture for high-performance computing applications. This arrangement may enable high-bandwidth optical communication between the xPU 540 and external network devices while providing the xPU 540 with high-bandwidth access to the HBM 546 stacks for memory-intensive computational tasks.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

As used herein, terms such as “above,” “below,” “over,” “under,” “adjacent,” “upper,” “top,” “lower,” “bottom,” “vertical,” “horizontal,” “lateral,” and similar positional or directional descriptors are used solely to describe the relative arrangement and orientation of features as illustrated in the drawings and are not intended to be limiting. Such terms do not require any particular orientation of the device in use, manufacture, or operation, and the described features may be oriented in any direction without departing from the scope of the present disclosure. Moreover, these terms are not intended to imply any absolute position, gravitational reference, or fixed spatial relationship, and components described as being positioned using positional or directional descriptors may be arranged in different relative positions, including inverted, rotated, or otherwise reoriented configurations, while still performing the same function in substantially the same way to achieve substantially the same result.

What is claimed is:

1. A package, comprising:
a photonic integrated circuit (PIC); and
an electronic integrated circuit (EIC) mounted on the PIC, the EIC comprising a network interface controller (NIC).

2. The package of claim 1, wherein the EIC further comprises a chip-to-chip interface configured to permit communication between the NIC and a processing unit.

3. The package of claim 2, wherein the chip-to-chip interface is a Universal Chiplet Interconnect Express (UCIe) interface.

4. The package of claim 3, further comprising a substrate on which the PIC is mounted, the substrate comprising a silicon bridge coupling the NIC with the processing unit.

5. The package of claim 1, wherein the EIC further comprises a plurality of serializer/deserializer (SerDes), each SerDes interfacing with the PIC.

6. The package of claim 5, wherein the PIC further comprises a plurality of tiles, each tile comprising:
a transceiver comprising an optical modulator and a photodetector; and
an optical switch configured to selectively couple optical signals between the transceiver and a bus waveguide.

7. The package of claim 6, wherein the plurality of tiles form a programmable optical network having dimensions greater than 24.8 mm by 32 mm.

8. The package of claim 1, wherein the PIC comprises a plurality of SRAM buffers configured to store data for retransmission buffering operations.

9. The package of claim 8, wherein the NIC is configured to communicate with the plurality of SRAM buffers to retrieve data for retransmission.

10. The package of claim 8, wherein the SRAM buffers are embedded in the PIC through heterogeneous integration.

11. A compute node, comprising:
a substrate;
a photonic integrated circuit (PIC) mounted on the substrate;
an electronic integrated circuit (EIC) mounted on the PIC, the EIC comprising a network interface controller (NIC) and a first chip-to-chip interface; and
a processing unit mounted on the substrate and comprising a second chip-to-chip interface in communication with the first chip-to-chip interface through the substrate.

12. The compute node of claim 11, wherein the first and second chip-to-chip interfaces are Universal Chiplet Interconnect Express (UCIe) interfaces.

13. The compute node of claim 11, wherein the substrate comprises a silicon bridge coupling the first and second chip-to-chip interfaces together.

14. The compute node of claim 11, further comprising a high bandwidth memory (HBM) mounted on the substrate and coupled to the processing unit.

15. The compute node of claim 11, wherein the EIC further comprises a plurality of serializer/deserializer (SerDes), each SerDes interfacing with the PIC.

16. The compute node of claim 11, wherein the PIC further comprises a plurality of tiles, each tile comprising:
a transceiver comprising an optical modulator and a photodetector; and
an optical switch configured to selectively couple optical signals between the transceiver and a bus waveguide.

17. The compute node of claim 16, wherein the plurality of tiles form a programmable optical network having dimensions greater than 24.8 mm by 32 mm.

18. The compute node of claim 11, wherein the PIC comprises a plurality of SRAM buffers configured to store data for retransmission buffering operations.

19. The compute node of claim 18, wherein the NIC is configured to communicate with the plurality of SRAM buffers to retrieve data for retransmission.

20. The compute node of claim 11, further comprising a pluggable optical connector configured to couple optical fibers to the PIC.
